(19) United States
(12) Patent Application Publication
(10) Pub. No.: US 2017/0033135 A1
(43) Pub. Date: Feb. 2, 2017

(54) INTEGRATED PASSIVE DEVICE ON SOI SUBSTRATE

(71) Applicant: SKYWORKS SOLUTIONS, INC., Woburn, MA (US)

(72) Inventors: David Scott WHITEFIELD, Andover, MA (US); Jerod F. MASON, Bedford, MA (US)

(21) Appl. No.: 15/219,596

(22) Filed: Jul. 26, 2016

Related U.S. Application Data
(60) Provisional application No. 62/197,750, filed on Jul. 28, 2015.

(51) Int. Cl. H01L 27/13; H01L 27/12; H01L 21/683; H01L 21/762; H01L 23/15; H01L 23/00

(52) U.S. Cl. CPC H01L 27/13; H01L 23/15; H01L 24/94; H01L 21/6835; H01L 21/76256; H01L 27/1207; H01L 2221/68368

(57) ABSTRACT

A method for fabricating dual-tier radio-frequency devices involves providing a silicon-on-insulator integrated circuit wafer having a semiconductor substrate and a plurality of integrated circuit devices formed thereon, at least partially removing the semiconductor substrate from a backside of the integrated circuit wafer, adding a low-loss replacement substrate to the backside of the integrated circuit wafer, and forming an integrated passive device over each of the plurality of integrated circuit devices after the adding of the low-loss replacement substrate to form a dual-tier wafer.

### CROSS-REFERENCE TO RELATED APPLICATION(S)

This application claims priority to U.S. Provisional Application No. 62/197,750, filed Jul. 28, 2015, and entitled INTEGRATED PASSIVE DEVICE ON SOI SUBSTRATE, the disclosure of which is hereby incorporated by reference in its entirety.

### BACKGROUND

Field

The present disclosure generally relates to the field of electronics, and more particularly, to radio-frequency (RF) modules and devices.

Description of Related Art

In electronics applications, passive and active devices can be utilized for various purposes, such as for routing and/or processing of radio-frequency (RF) signals in wireless devices.

### SUMMARY

In some implementations, the present disclosure relates to a method for fabricating dual-tier radio-frequency devices, the method comprising providing a silicon-on-insulator integrated circuit wafer having a semiconductor substrate and a plurality of integrated circuit devices formed thereon, at least partially removing the semiconductor substrate from a backside of the integrated circuit wafer, adding a low-loss replacement substrate to the backside of the integrated circuit wafer, and forming an integrated passive device over each of the plurality of integrated circuit devices after the adding of the low-loss replacement substrate to form a dual-tier wafer. The method may further comprise singulating the dual-tier wafer to form a plurality of dual-tier radio-frequency devices.

In certain embodiments, forming the integrated passive devices over each of the plurality of integrated circuit devices involves bonding an integrated passive device wafer to the integrated circuit wafer using a wafer bonding process.

The method may further comprise applying a carrier wafer on a front-side of the integrated circuit wafer prior to said at least partially removing the semiconductor substrate. In certain embodiments, the replacement substrate includes a high-resistivity substrate. The replacement substrate may include glass.

The method may further comprise applying an interface layer to the backside of the integrated circuit wafer prior to said adding the low-loss replacement substrate. In certain embodiments, each of the passive devices includes one or more of a resistor, a capacitor, and an inductor. In certain embodiments, forming an integrated passive device over each of the plurality of integrated circuit devices involves forming a plurality of dielectric layers on a front-side of the integrated circuit wafer and forming one or more electrical connections therein.

In some implementations, the present disclosure relates to a dual-tier semiconductor die comprising a first tier including an integrated circuit device disposed on a low-loss substrate and a second tier disposed on the first tier, the second tier including an integrated passive device. The second tier may be bonded to the first tier according to a wafer bonding process.

In certain embodiments, the low-loss substrate is a high-resistivity substrate. The low-loss substrate may be glass. The dual-tier semiconductor die may further comprise an interface layer formed between the low-loss substrate and the integrated circuit device. In certain embodiments, the integrated passive device includes one or more of a resistor, a capacitor, and an inductor. The second tier may include a plurality of dielectric layers and one or more electrical connections.

In some implementations, the present disclosure relates to a radio-frequency module comprising a packaging substrate configured to receive a plurality of components, and a dual tier die disposed on the packaging substrate and having a first tier including an integrated circuit device disposed on a low-loss substrate, and a second tier disposed on the first tier, the second tier including an integrated passive device. The second tier may be bonded to the first tier according to a wafer bonding process. The low-loss substrate may be a high-resistivity substrate. In certain embodiments, the low-loss substrate is glass.

In some implementations, the present disclosure relates to a method comprising forming a field-effect transistor (FET) over a semiconductor substrate layer and an oxide layer formed on the substrate layer, forming one or more first electrical connections to the FET, covering at least a portion of the one or more first electrical connections with a passivation layer, and forming a passive device and one or more second electrical connections on top of the passivation layer.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 shows an example of a field-effect transistor (FET) device having an active FET implemented on a substrate, and a region below the active FET configured to include one or more features to provide one or more desirable operating functionalities for the active FET.

FIG. 2 shows an example of a FET device having an active FET implemented on a substrate, and a region above the active FET configured to include one or more features to provide one or more desirable operating functionalities for the active FET.

FIG. 3 shows that in some embodiments, a FET device can include both of the regions of FIGS. 1 and 2 relative to an active FET.

FIG. 4 shows an example FET device implemented as an individual silicon-on-insulator (SOI) unit.

FIG. 5 shows that in some embodiments, a plurality of individual SOI devices similar to the example SOI device of FIG. 4 can be implemented on a wafer.

FIG. 6A shows an example wafer assembly having a first wafer and a second wafer positioned over the first wafer.

FIG. 6B shows an unassembled view of the first and second wafers of the example of FIG. 6A.

FIG. 7 shows a terminal representation of an SOI FET according to one or more embodiments.

FIGS. 8A and 8B show side sectional and plan views, respectively, of an example SOI FET device according to one or more embodiments.

FIG. 9 shows a side sectional view of an SOI substrate that can be utilized to form an SOI FET device according to one or more embodiments.

FIG. 10 shows a side sectional view of an SOI FET device according to one or more embodiments.

FIG. 11 shows a process that can be implemented to facilitate fabrication of an SOI FET device having one or more features as described herein.

FIG. 12 shows examples of various stages of the fabrication process of FIG. 11.

FIG. 13 shows that in some embodiments, an SOI FET device can have its contact layer having one or more features as described herein biased by, for example, a substrate bias network.

FIG. 14 shows an example of a radio-frequency (RF) switching configuration having an RF core and an energy management (EM) core.

FIG. 15 shows an example of the RF core of FIG. 14, in which each of the switch arms includes a stack of FET devices.

FIG. 16 shows an example of the biasing configuration of FIG. 13, implemented in a switch arm having a stack of FETs as described in reference to FIG. 15.

FIG. 17 illustrates an active die connected to a passive die according to one or more embodiments.

FIG. 18 illustrates a cross-sectional view of an integrated passive die (IPD) according to one or more embodiments.

FIG. 19 shows a process that can be implemented to facilitate fabrication of an active and passive device having one or more features as described herein.

FIG. 20 shows examples of various stages of the fabrication process of FIG. 19.

FIGS. 21A and 21B show plan and side views, respectively, of a packaged module having one or more features as described herein.

FIG. 22 shows a schematic diagram of an example switching configuration that can be implemented in a module according to one or more embodiments.

FIG. 23 depicts an example wireless device having one or more advantageous features described herein.

### DETAILED DESCRIPTION OF SOME EMBODIMENTS

The headings provided herein are for convenience only and do not necessarily affect the scope or meaning of the claimed invention.

Introduction

Disclosed herein are various examples of a field-effect transistor (FET) device having one or more regions relative to an active FET portion configured to provide a desired operating condition for the active FET. In such various examples, terms such as FET device, active FET portion, and FET are sometimes used interchangeably, with each other, or some combination thereof. Accordingly, such interchangeable usage of terms should be understood in appropriate contexts.

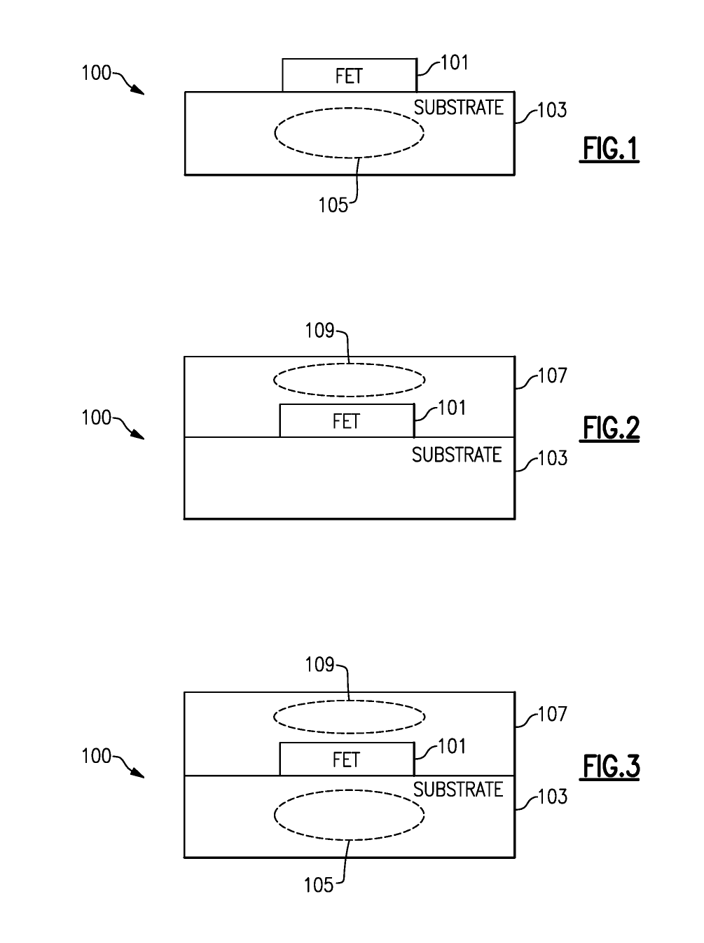

FIG. 1 shows an example of a FET device 100 having an active FET 101 implemented on a substrate 103. As described herein, such a substrate can include one or more layers configured to facilitate, for example, operating functionality of the active FET, processing functionality for fabrication and support of the active FET, etc. For example, if the FET device 100 is implemented as a silicon-on-Insulator (SOI) device, the substrate 103 can include an insulator layer such as a buried oxide (BOX) layer, an interface layer, and a handle wafer layer.

FIG. 1 further shows that in some embodiments, a region 105 below the active FET 101 can be configured to include one or more features to provide one or more desirable operating functionalities for the active FET 101. For the purpose of description, it will be understood that relative positions above and below are in the example context of the active FET 101 being oriented above the substrate 103 as shown. Accordingly, some or all of the region 105 can be implemented within the substrate 103. Further, it will be understood that the region 105 may or may not overlap with the active FET 101 when viewed from above (e.g., in a plan view).

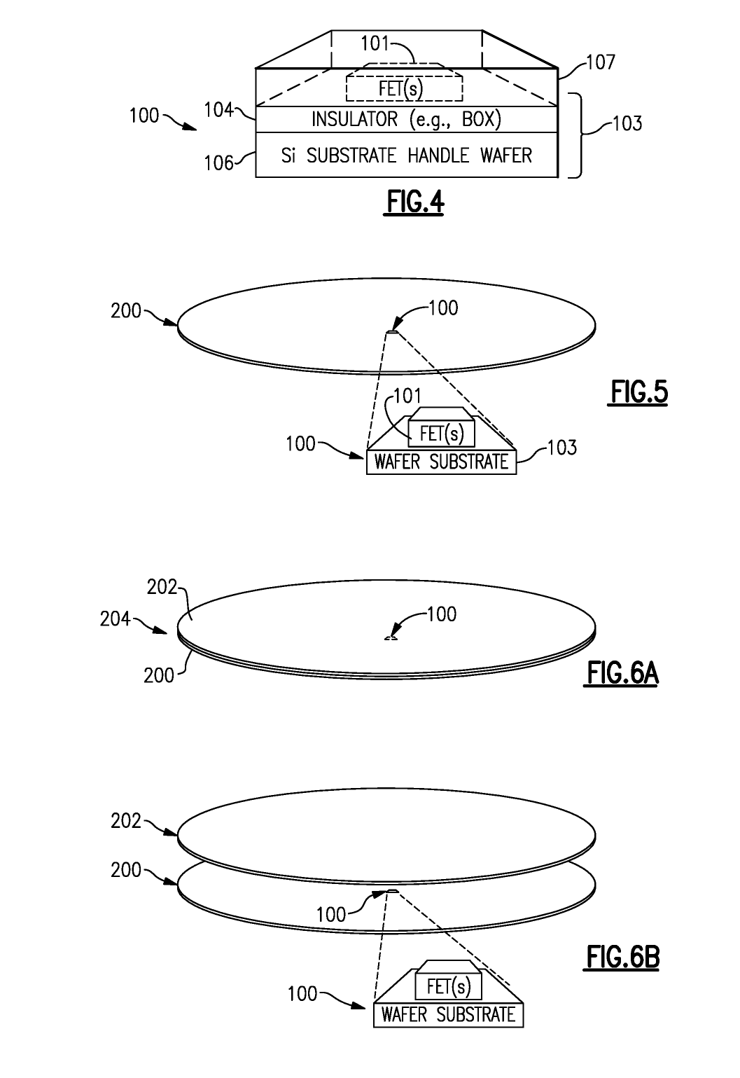

FIG. 2 shows an example of a FET device 100 having an active FET 101 implemented on a substrate 103. As described herein, such a substrate can include one or more layers configured to facilitate, for example, operating functionality of the active FET 100, processing functionality for fabrication and support of the active FET 100, etc. For example, if the FET device 100 is implemented as a silicon-on-Insulator (SOI) device, the substrate 103 can include an insulator layer such as a buried oxide (BOX) layer, an interface layer, and a handle wafer layer.

In the example of FIG. 2, the FET device 100 is shown to further include an upper layer 107 implemented over the substrate 103. In some embodiments, such an upper layer can include, for example, a plurality of layers of metal routing features and dielectric layers to facilitate, for example, connectivity functionality for the active FET 100.

FIG. 2 further shows that in some embodiments, a region 109 above the active FET 101 can be configured to include one or more features to provide one or more desirable operating functionalities for the active FET 101. Accordingly, some or all of the region 109 can be implemented within the upper layer 107. Further, it will be understood that the region 109 may or may not overlap with the active FET 101 when viewed from above (e.g., in a plan view).

FIG. 3 shows an example of a FET device 100 having an active FET 101 implemented on a substrate 103, and also having an upper layer 107. In some embodiments, the substrate 103 can include a region 105 similar to the example of FIG. 1, and the upper layer 107 can include a region 109 similar to the example of FIG. 2.

Examples related to some or all of the configurations of FIGS. 1-3 are described herein in greater detail.

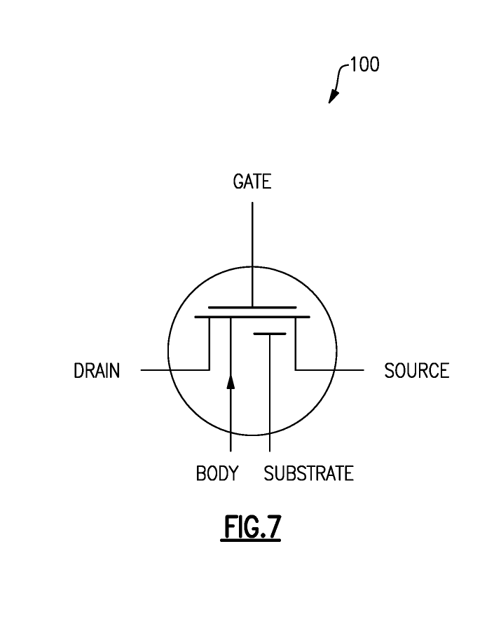

In the examples of FIGS. 1-3, the FET devices 100 are depicted as being individual units (e.g., as semiconductor die). FIGS. 4-6 show that in some embodiments, a plurality of FET devices having one or more features as described herein can be fabricated partially or fully in a wafer format, and then be singulated to provide such individual units.

For example, FIG. 4 shows an example FET device 100 implemented as an individual SOI unit. Such an individual SOI device can include one or more active FETs 101 implemented over an insulator such as a BOX layer 104 which is itself implemented over a handle layer such as a silicon (Si) substrate handle wafer 106. In the example of FIG. 4, the BOX layer 104 and the Si substrate handle wafer 106 can collectively form the substrate 103 of the examples of FIGS. 1-3, with or without the corresponding region 105.

In the example of FIG. 4, the individual SOI device 100 is shown to further include an upper layer 107. In some embodiments, such an upper layer can be the upper layer 103 of FIGS. 2 and 3, with or without the corresponding region 109.

FIG. 5 shows that in some embodiments, a plurality of individual SOI devices similar to the example SOI device 100 of FIG. 4 can be implemented on a wafer 200. As shown, such a wafer can include a wafer substrate 103 that includes a BOX layer 104 and a Si handle wafer layer 106 as described in reference to FIG. 4. As described herein, one or more active FETs can be implemented over such a wafer substrate.

In the example of FIG. 5, the SOI device 100 is shown without the upper layer (107 in FIG. 4). It will be understood that such a layer can be formed over the wafer substrate 103, be part of a second wafer, or any combination thereof.

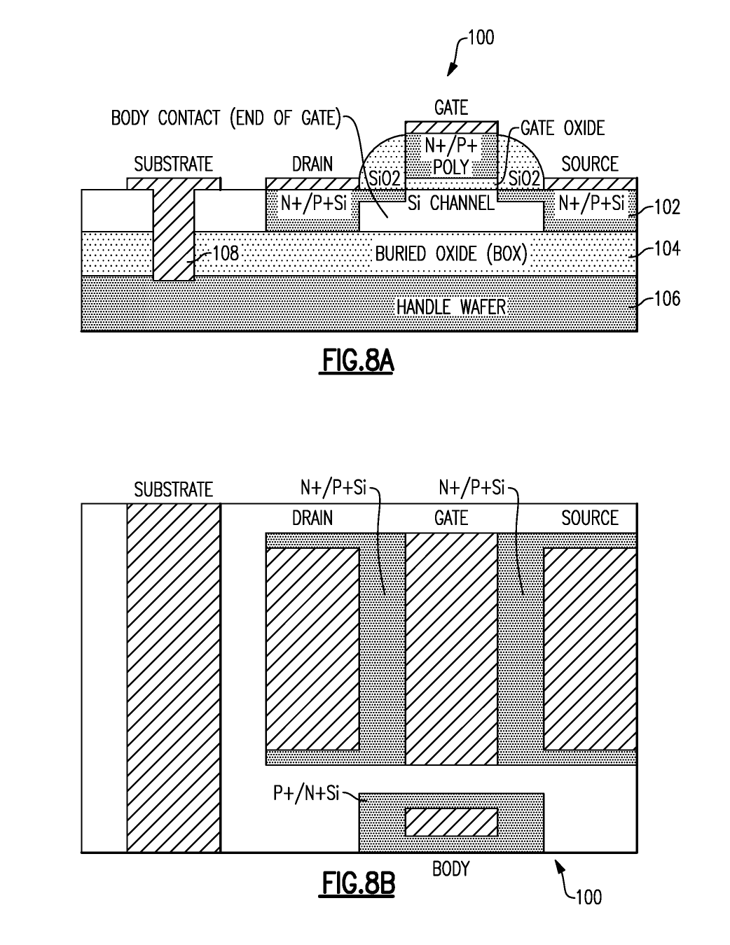

FIG. 6A shows an example wafer assembly 204 having a first wafer 200 and a second wafer 202 positioned over the first wafer 200. FIG. 6B shows an unassembled view of the first and second wafers 200, 202 of the example of FIG. 6A.

In some embodiments, the first wafer 200 can be similar to the wafer 200 of FIG. 5. Accordingly, the first wafer 200 can include a plurality of SOI devices 100 such as the example of FIG. 4. In some embodiments, the second wafer 202 can be configured to provide, for example, a region (e.g., 109 in FIGS. 2 and 3) over a FET of each SOI device 100, and/or to provide temporary or permanent handling wafer functionality for process steps involving the first wafer 200.

Examples of SOI Implementation of FET Devices

Silicon-on-Insulator (SOI) process technology is utilized in many radio-frequency (RF) circuits, including those involving high performance, low loss, high linearity switches. In such RF switching circuits, performance advantage typically results from building a transistor in silicon, which sits on an insulator such as an insulating buried oxide (BOX). The BOX typically sits on a handle wafer, typically silicon, but can be glass, borosilicon glass, fused quartz, sapphire, silicon carbide, or any other electrically-insulating material.

Typically, an SOI transistor is viewed as a 4-terminal field-effect transistor (FET) device with gate, drain, source, and body terminals. However, an SOI FET can be represented as a 5-terminal device, with an addition of a substrate node. Such a substrate node can be biased and/or be coupled one or more other nodes of the transistor to, for example, improve both linearity and loss performance of the transistor. Various examples related to such a substrate node and biasing/coupling of the substrate node are described herein in greater detail.

In some embodiments, such a substrate node can be implemented with a contact layer having one or more features as described herein to allow the contact layer to provide a desirable functionality for the SOI FET. Although various examples are described in the context of RF switches, it will be understood that one or more features of the present disclosure can also be implemented in other applications involving FETs.

An SOI transistor is viewed as a 4-terminal field-effect transistor (FET) device with gate, drain, source, and body terminals; or alternatively, as a 5-terminal device, with an addition of a substrate node. Such a substrate node can be biased and/or be coupled one or more other nodes of the transistor to, for example, improve linearity and/or loss performance of the transistor. Various examples related to SOI and/or other semiconductor active and/or passive devices are described herein in greater detail. Although various examples are described in the context of RF switches, it will be understood that one or more features of the present disclosure can also be implemented in other applications involving FETs and/or other semiconductor devices.

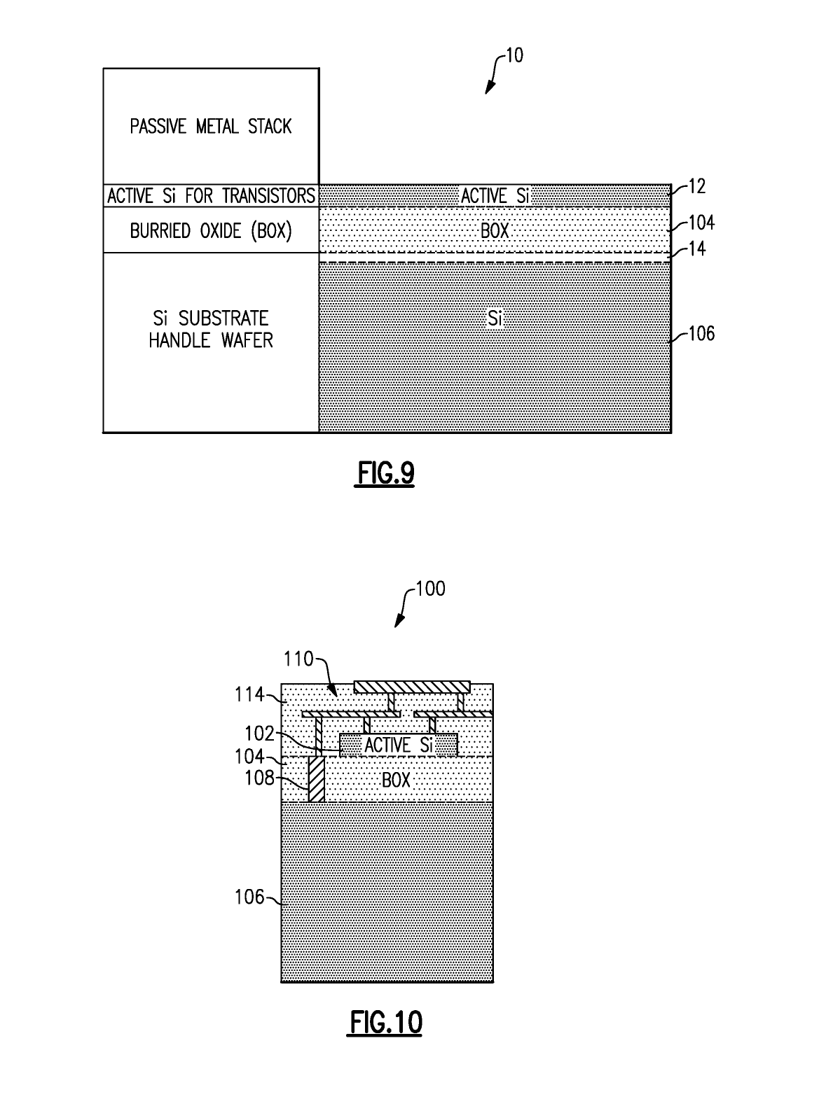

FIG. 7 shows an example 5-terminal representation of an SOI FET 100 having nodes associated with a gate, a source, a drain, a body, and a substrate. It will be understood that in some embodiments, the source and the drain nodes can be reversed.

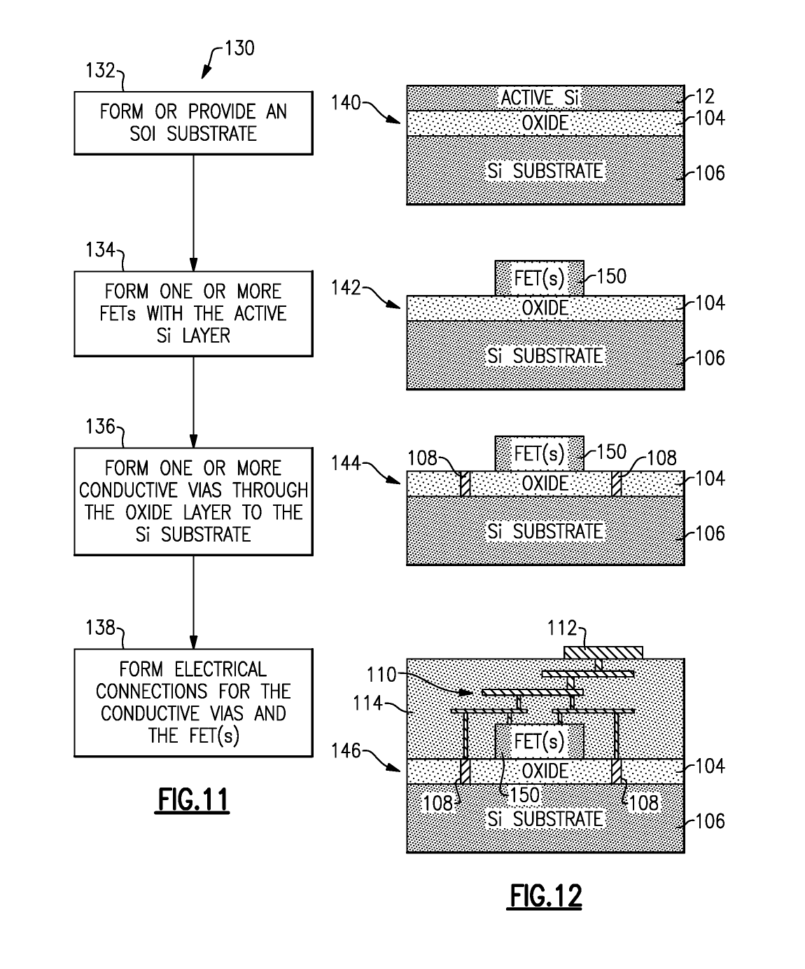

FIGS. 8A and 8B show side sectional and plan views of an example SOI FET 100. While the example FET 100 is illustrated as having a substrate node, principles disclosed herein may be applicable with respect to FET devices not having a substrate contact. The substrate of the FET 100 can be, for example, a silicon substrate associated with a handle wafer 106. Although described in the context of such a handle wafer, it will be understood that the substrate does not necessarily need to have material composition and/or functionality generally associated with a handle wafer. Furthermore, handle wafer and/or other substrate layers like that shown in FIG. 8A may be referred to herein as “bulk substrate,” “bulk silicon,” “handle substrate,” “stabilizing substrate,” or the like, and may comprise any suitable or desirable material, depending on the application.

An insulator layer such as a buried oxide (BOX) layer 104 is shown to be formed over the handle wafer 106, and a FET structure is shown to be formed in an active silicon device 102 over the BOX layer 104. In various examples described herein, and as shown in FIGS. 8A and 8B, the FET structure can be configured as an NPN or PNP device.

In the examples of FIGS. 8A and 8B, terminals for the gate, source, drain and body are shown to be configured and provided so as to allow operation of the FET. The BOX layer 104 may be formed on the semiconductor substrate 106. In certain embodiments, the BOX layer 104 can be formed from materials such as silicon dioxide or sapphire. Source and drain may be p-doped (or n-doped) regions whose exposed surfaces generally define rectangles. Source/drain regions can be configured so that source and drain functionalities are reversed. FIGS. 8A and 8B further show that a gate can be formed so as to be positioned between the source and the drain. The example gate is depicted as having a rectangular shape that extends along with the source and the drain. The FET 100 may further include a body contact.

A substrate terminal is shown to be electrically connected to the substrate (e.g., handle wafer) 106 through an electrically conductive feature 108 extending through the BOX layer 104. Such an electrically conductive feature can include, for example, one or more conductive vias, one or more conductive trenches, or any combination thereof. Electrically conductive features such as conductive vias and/or trenches may further be used to connect to the drain, source, gate and/or body terminals of the FET in certain embodiments. Various examples of how such an electrically conductive feature can be implemented are described herein in greater detail.

In some embodiments, a substrate connection, such as in the example of FIGS. 8A and 8B, can be connected to ground to, for example, avoid an electrically-floating condition associated with the substrate. Such a substrate connection for grounding may include a seal-ring implemented at an outermost perimeter of a die. In some embodiments, a substrate connection such as the example of FIGS. 8A and 8B can be utilized to bias the substrate 106, to couple the substrate with one or more nodes of the corresponding FET (e.g., to provide RF feedback), or any combination thereof. Such use of the substrate connection can be configured to, for example, improve RF performance and/or reduce cost by eliminating or reducing expensive handle-wafer treatment processes and layers. Such performance improvements can include, for example, improvements in linearity, loss and/or capacitance performance. The foregoing biasing of the substrate node can be, for example, selectively applied to achieve desired RF effects only when needed or desired. For example, bias points for the substrate node can be connected to envelope-tracking (ET) bias for a power amplifier (PA) to achieve distortion cancelation effects. In some embodiments, a substrate connection for providing the foregoing example functionalities can be implemented as a seal-ring configuration similar to the grounding configuration, or other connection configurations.

Formations of the source and drain regions, and the substrate and/or body contacts can be achieved by a number of known techniques. In some embodiments, the source and drain regions can be formed adjacent to the ends of their respective upper insulator layers, and the junctions between the body and the source/drain regions on the opposing sides of the body can extend substantially all the way down to the top of the buried oxide layer. Such a configuration can provide, for example, reduced source/drain junction capacitance. To form a body contact for such a configuration, an additional gate region can be provided.

FIG. 9 shows a side sectional view of an SOI substrate 10 that can be utilized to form an SOI FET 100, as shown in FIG. 10, which may have an electrical connection for a substrate layer 106 (e.g., Si handle layer). In FIG. 9, an insulator layer such as a BOX layer 104 is shown to be formed over the Si handle layer 106. An active Si layer 12 is shown to be formed over the BOX layer 104.

In FIG. 10, an active Si device 102 is shown to be formed from the active Si layer 12 of FIG. 9. One or more electrically conductive features 108 such as vias are shown to be implemented through the BOX layer 104, relative to the active Si device 102. Such conductive features can allow the Si handle layer 106 to be coupled to the active Si device (e.g., a FET), be biased, or any combination thereof. Such coupling and/or biasing can be facilitated by, for example, a metal stack 110. In some embodiments, such a metal stack can allow for certain conductive features of the FET 100 to be electrically connected to a terminal 112, or other electrically-coupled element. In the example of FIG. 10, a passivation layer 114 can be formed to cover some or all of the connections/metal stack and/or active device 102.

In some embodiments, a trap-rich layer 14 (shown in FIG. 9) can be implemented between the BOX layer 104 and the Si handle layer 106. However, and as described herein, the electrical connection to the Si handle layer 106 through the conductive feature(s) 108 can eliminate or reduce the need for such a trap-rich layer, which is typically present to control charge at an interface between the BOX layer 104 and the Si handle layer 106, and can involve relatively costly process steps.

Aside from the foregoing example of eliminating or reducing the need for a trap-rich layer, an electrical connection to the Si handle layer 106 can provide a number of advantageous features. For example, the conductive feature(s) 108 can allow forcing of excess charge at the BOX/Si handle interface to thereby reduce unwanted harmonics. In another example, excess charge can be removed through the conductive feature(s) 108 to thereby reduce the off-capacitance (Coff) of the SOI FET. In yet another example, the presence of the conductive feature(s) 108 can lower the threshold of the SOI FET to thereby reduce the on-resistance (Ron) of the SOI FET.

FIG. 11 shows a process 130 that can be implemented to fabricate an SOI FET having one or more features as described herein. FIG. 12 shows examples of various stages/structures associated with the various steps of the fabrication process of FIG. 11.

In block 132 of FIG. 11, an SOI substrate can be formed or provided. In state 140 of FIG. 12, such an SOI substrate can include an Si substrate 106 such as an Si handle layer, an oxide layer 104 over the Si substrate 106, and an active Si layer 12 over the oxide layer 104. Such an SOI substrate may or may not have a trap-rich layer between the oxide layer 104 and the Si substrate 106.

In block 134 of FIG. 11, one or more FETs can be formed with the active Si layer. In state 142 of FIG. 12, such FET(s) is depicted as 150.

In block 136 of FIG. 11, one or more conductive vias can be formed through the oxide layer 104, to the Si substrate 106, and relative to the FET(s) 150. In state 144 of FIG. 12, such conductive via(s) are identified by reference number 108. As described herein, such an electrical connection through the oxide layer 104 to the Si substrate 106 can also be implemented utilizing other conductive features such as one or more conductive trenches. Certain embodiments may not include the illustrated conductive via features 108.

In the example of FIGS. 11 and 12, it will be understood that blocks 134 and 136 may or may not be performed in the example sequence shown. In some embodiments, conductive feature(s) such as one or more deep trenches can be formed and filled with poly prior to the formation of the FET(s). In some embodiments, such conductive feature(s) can be formed (e.g., cut and filled with a metal such as tungsten (W) after the formation of the FET(s). It will be understood that other variations in sequences associated with the example of FIGS. 11 and 12 can also be implemented.

In block 138 of FIG. 11, electrical connections can be formed for the conductive vias and the FET(s). In state 146 of FIG. 12, such electrical connections are depicted as a metallization stack collectively identified by reference number 110. Such a metal stack 110 can electrically connect the FET(s) 150 and the conductive vias 108 to one or more terminals 112, or other electrical element or device (e.g., active or passive device). In the example state 146 of FIG. 12, a passivation layer 114 is shown to be formed to cover some or all of the connections/metallization stack 110 and/or FET(s) 150.

FIG. 13 shows that in some embodiments, an SOI FET 700 having one or more features as described herein can have its gate node biased by a gate bias network 756, its body node biased by a body bias network 754 and/or its substrate node biased by a substrate bias network 752. Examples related to such gate and body bias networks are described in U.S. Pub. No. 2014/0009274, titled “Circuits, Devices, Methods and Applications Related to Silicon-on-Insulator Based Radio-Frequency Switches,” which is hereby incorporated by reference in its entirety.

FIGS. 14-16 show that in some embodiments, SOI FETs having one or more features as described herein can be implemented in RF switching applications.

FIG. 14 shows an example of an RF switching configuration 760 having an RF core 762 and an energy management (EM) core 764. Additional details concerning such RF and EM cores are described in U.S. Pub. No. 2014/0009274, titled “Circuits, Devices, Methods and Applications Related to Silicon-on-Insulator Based Radio-Frequency Switches,” which is incorporated by reference herein in its entirety. The example RF core 762 of FIG. 14 is shown as a single-pole-double-throw (SPDT) configuration in which series arms of transistors 700a, 700b are arranged between a pole and first and second throws, respectively. Nodes associated with the first and second throws are shown to be coupled to ground through their respective shunt arms of transistors 700c, 700d.

In the example of FIG. 14, some or all of the transistors 700a-700d can include electrical connections to respective substrates as described herein. Such electrical connections to the substrates can be utilized to provide bias to the substrates and/or provide coupling with other portion(s) of the respective transistors. Furthermore, some or all of the transistors 700a-700d may have associated therewith one or more integrated passive device features in one or more layers of the structure, as described in greater detail below.

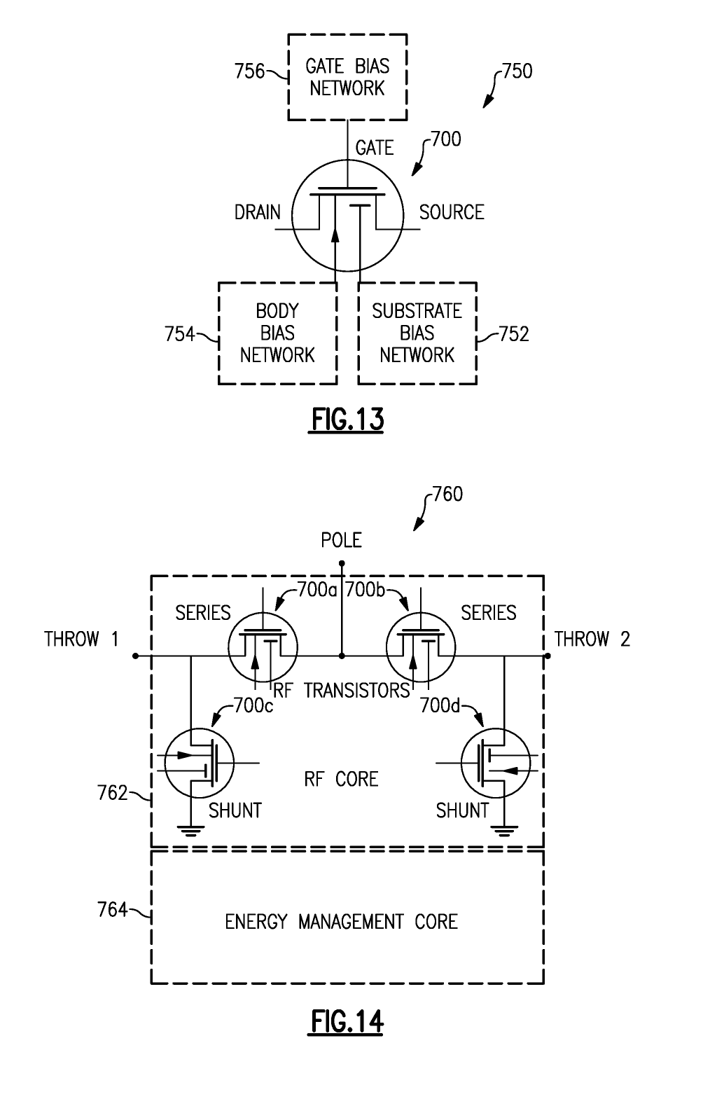

FIG. 15 shows an example of the RF core 762 of FIG. 14, in which each of the switch arms 700a-700d includes a stack of FET devices. For the purpose of description, each FET in such a stack can be referred to as a FET, a stack can be collectively referred to as a FET, or any combination thereof. In the example of FIG. 15, each FET in the corresponding stack is shown to include a substrate node connection as described herein. It will be understood that some or all of the FET devices in the RF core 762 can include such substrate node connections.

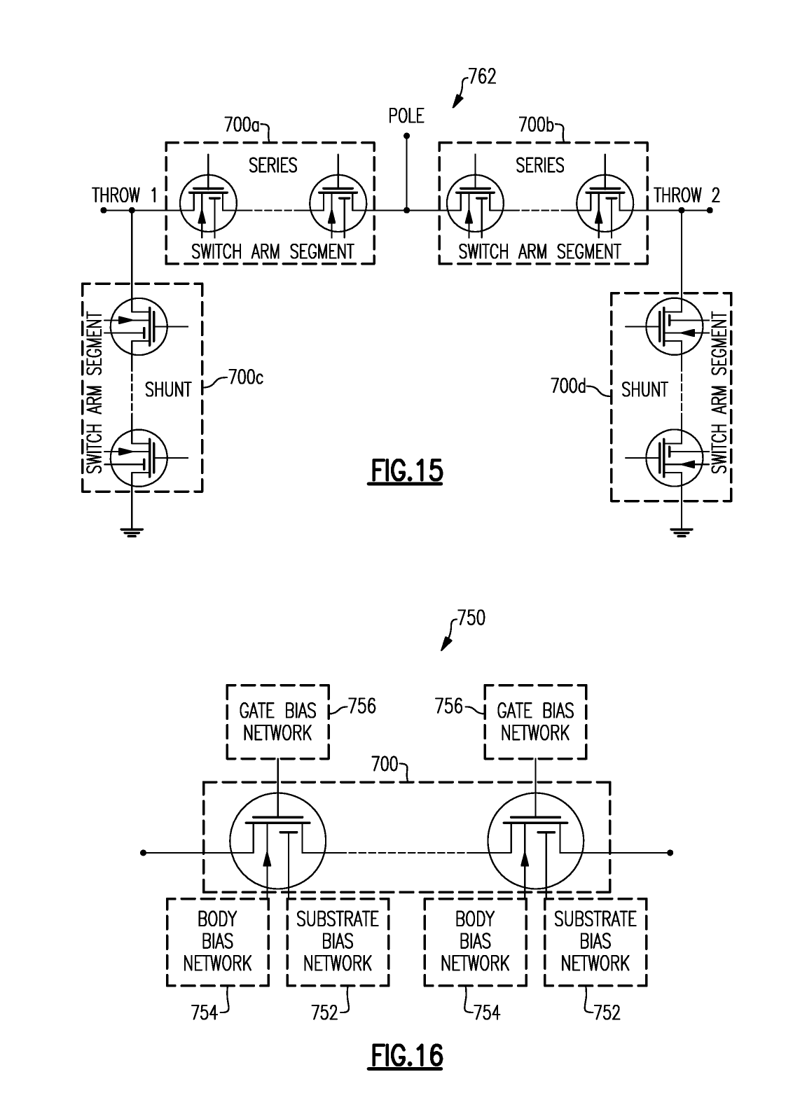

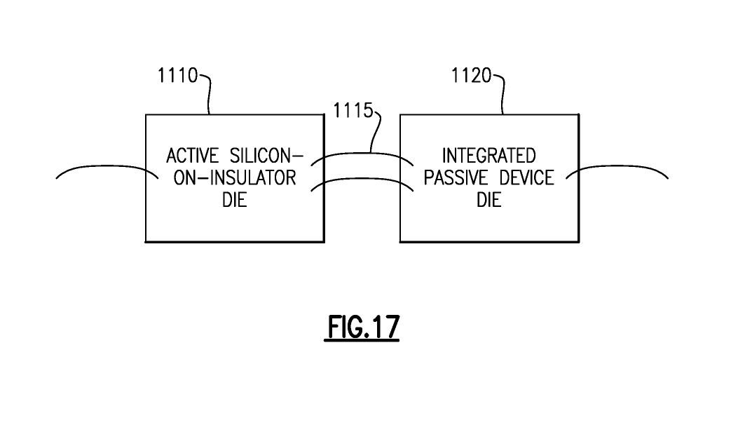

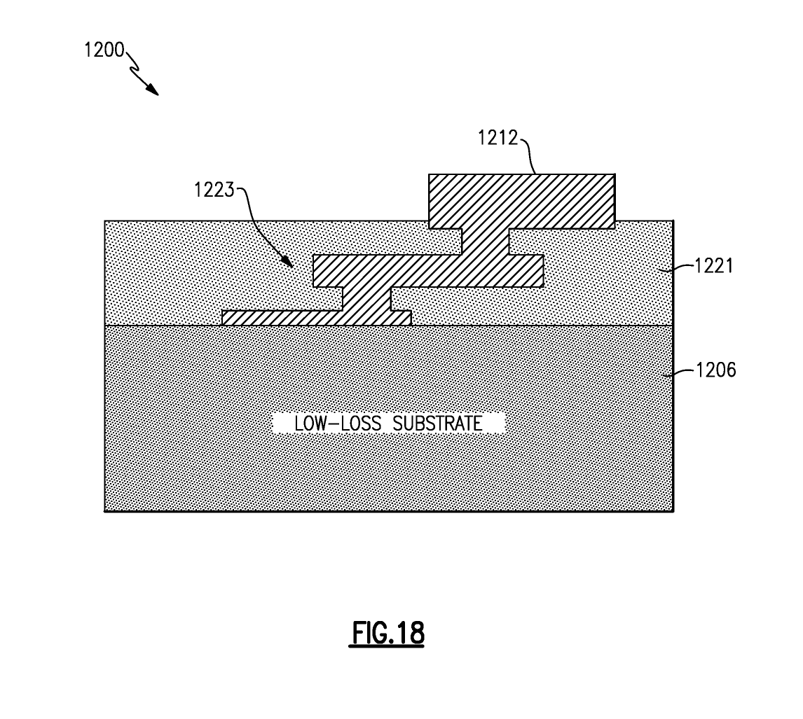

FIG. 16 shows an example of the biasing configuration 750 of FIG. 13, implemented in a switch arm having a stack of FETs 700 as described in reference to FIG. 15. In the example of FIG. 16, each FET in the stack can be biased with a separate gate bias network 756, body bias network 754 and/or substrate bias network 752, the FETs in the stack can be biased with a plurality of gate bias networks 756, body bias networks 754 and/or substrate bias networks 752, all of the FETs in the stack can be biased with a common gate bias network, body bias network and/or substrate bias network, or any combination thereof.

Active/Passive Device Integration

The foregoing descriptions of active semiconductor devices may be utilized for various radio-frequency (RF) applications, such as power amplifiers, switches, and the like. In addition to active devices and/or dies, in certain embodiments, one or more relatively high-performance passive devices may also be utilized in connection with the active device(s). Such passive device(s) may be packaged as a separate “Integrated Passive Device (IPD),” or “Integrated Passive Component (IPC),” which may be desirable in view of size, cost and/or functionality considerations. Various functional blocks, such as impedance matching circuits, harmonic filters, couplers, baluns and power combiners/dividers are examples of devices that may be implemented in IPDs. IPDs may generally be fabricated using standard wafer fabrication technologies, such as thin-film and photolithography processing, and may be designed as, for example, flip-chip-mountable or wire-bondable components. In certain embodiments, an IPD includes a substrate comprising silicon, alumina, glass, or other thin-film substrate material.

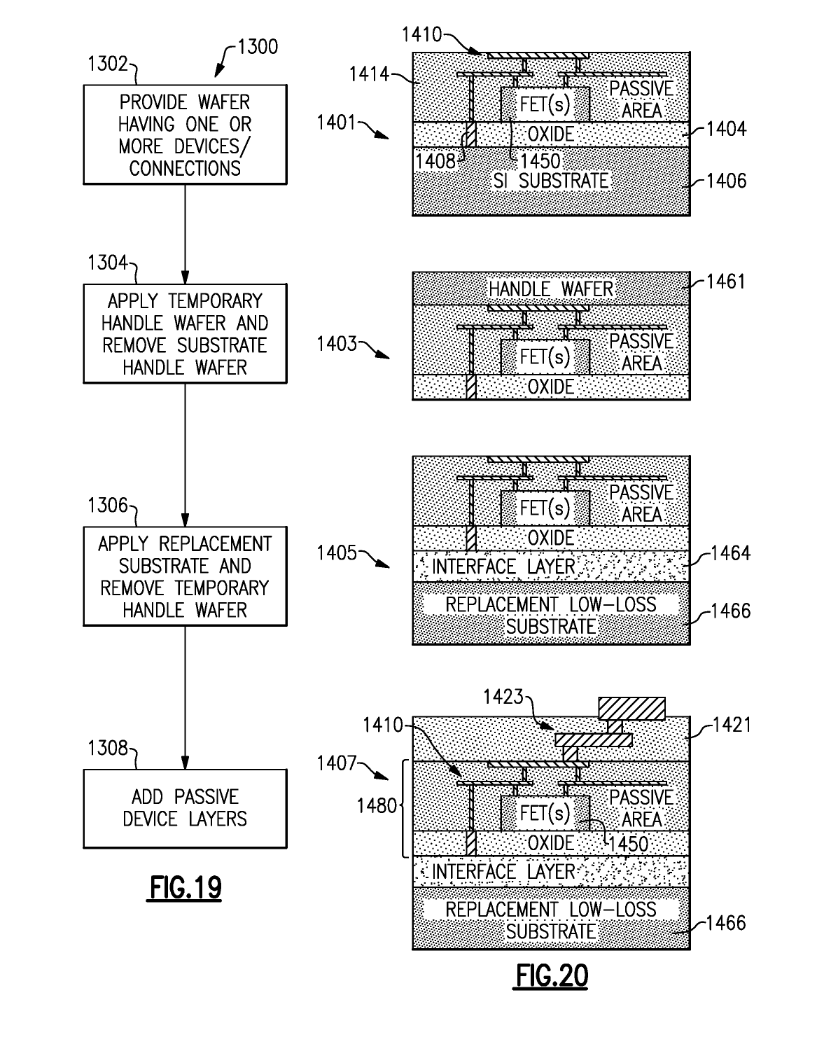

As described above, an active transistor device may be biased using one or more passive elements. Such biasing elements may be implemented in an IPD in certain embodiments. In addition, filtering, matching, coupling, or other functionality may be implemented in one or more IPDs electrically coupled to an active RF die. FIG. 17 illustrates an active die 1110 connected to a passive die 1120 (e.g., IPD) according to one or more embodiments. In one embodiment, the active die 1110 may be a switching device, wherein the passive die 1120 provides filtering functionality for the switching device. In another embodiment, the active die 1110 may be a power amplifier (PA) die (e.g., silicon PA), wherein the passive die 1120 provides matching functionality for the active die 1110. In another embodiment, the passive die 1120 may provide passive coupling functionality for the active die 1110.

According to certain fabrication processes, one type of process may be implemented in manufacturing the active die 1110, while a separate process may be implemented in manufacturing the passive die 1120; the two separately-manufactured dies may be subsequently connected using electrical connectors 1115, such as conductive wirebonds, traces, contacts, and/or combinations thereof. The two dies may be connected to one another in a side-by-side configuration in a single package.

FIG. 18 illustrates a cross-sectional view of an integrated passive die (IPD) 1200 according to one or more embodiments. In a two-die solution, as shown in FIG. 17, an IPD 1200 including one or more passive devices 1212 may be formed on a low-loss or high-linearity substrate 1206, such as glass. The IPD 1200 may be manufactured using known wafer-processing techniques. In certain embodiments, one or more metal contacts 1223 formed from one or more metal layers. The metal layers may be used for form certain passive devices and or contacts 1212. For example, the metal layers may be used to form capacitor(s) (e.g., metal-insulator-metal (MIM) capacitor(s)), inductor(s) (e.g., metal spiral inductor(s)), resistor(s), contact pad(s), coupler(s), or other elements or devices. In certain embodiments, at least a portion of the metal elements 1223 is covered by a dielectric material 1221, or the like, which may be applied using standard semiconductor processes. In certain embodiments, the dielectric layer 1221 may comprise oxide or other dielectric material, such as Polyimide (PI), Polybenzoxazole (PBO), Benzocyclobuten (BCB), or the like.

Certain processes for building passive devices on glass substrates can present difficulties not present in some silicon processes. For example, automated fabrication tools relying on vision systems may not be as compatible with glass processing. In addition, glass may be less pure than silicon, and/or may have different density characteristics, and therefore processing tools designed for silicon processes may not be effective in such processes. Furthermore, certain silicon (e.g., SOI) fabrication systems/process may not be suited to apply the relatively thick metal layers associated with certain passive devices in a cost effective way. Therefore, in order to implement the two-die solution illustrated in FIG. 17, separate fabrication tools may be required for each process.

Certain embodiments disclosed herein provide for integrated passive device processing on SOI layer transfer substrates, which may provide reduced size and/or increased linearity performance for an RF product that includes both active SOI components (e.g., switches, low-noise amplifiers (LNAs), PAs and/or combinations thereof) as well as integrated passive devices (e.g., resistors, capacitors, inductors, and the like). For example, disclosed herein are dual-tier semiconductor structures and solutions having a first tier comprising one or more layers including one or more active semiconductor devices (e.g., FETs) and/or electrical connections associated therewith, as well as a second tier, which may be disposed at least partially above the active device(s), the second tier comprising one or more passive devices (e.g., resistor(s), capacitor(s), inductor(s), or the like). The second tier may be formed/fabricated on the first-tier wafer or structure. For example, the second tier may be formed using a wafer process that utilizes the first tier wafer structure as a starting wafer structure for forming the passive device(s) thereon.

The term “dual-tier” is used herein according to its broad and ordinary meaning and may be used to refer to a structure including a first tier comprising a wafer having formed thereon a plurality of active integrated circuit devices. For example, the first tier of a dual-tier structure according to embodiments disclosed herein may comprise an integrated circuit wafer, wherein “integrated circuit wafer” is used according to its broad and ordinary meaning understood by those having ordinary skill in the art. For example, the integrated circuit wafer may comprise a plurality of active devices, wherein the wafer may be singulated or sub-divided to produce a plurality of circuit dies or units. In certain embodiments, the first-tier wafer may comprise a silicon-on-insulator (SOI) integrated circuit wafer.

However, adding passive devices onto SOI processes to form dual-tier structure(s), as described herein, may negatively impact performance in certain embodiments due to reduced metal thickness vis-à-vis traditional IPD processing and/or substrate linearity. Furthermore, final IPD processing on SOI process can be challenging in view of difficulties often associated with glass or other high-resistivity substrate processing.

Certain embodiments disclosed herein involve performing a layer transfer process to replace an existing SOI substrate with a standard IPD substrate, such as glass or other low-loss substrate. The replacement layer transfer substrate may be used as the starting wafer for the IPD process. That is, the replacement layer transfer substrate with one or more active devices formed thereon, may provide the first tier of a dual-tier integrated active and passive device wafer or unit (e.g., die). IPD processing on SOI processes may provide various benefits, such as a single die (e.g., dual-tier) solution, rather than a two-die solution including two separate, single-tier units/dies as shown in FIG. 17. Furthermore, reduced complexity/number of interconnects may be involved in connecting the active SOI device(s) with the integrated passive device(s), which may result in improved performance. Additional benefits, such as reduced size/footprint, increased flexibility for active devices and passive devices to be brought into close proximity, and other benefits.

With regard to dual-tier devices according to embodiments disclosed herein, an SOI wafer may be used as a substrate for an integrated passive device, which may provide various benefits, such as simplified processing and/or cost savings compared to separate active and passive dies, as shown in FIG. 17. That is, the SOI device layer may serve as a first tier of a dual-tier structure, wherein a second tier comprising one or more passive devices is formed above the first tier.

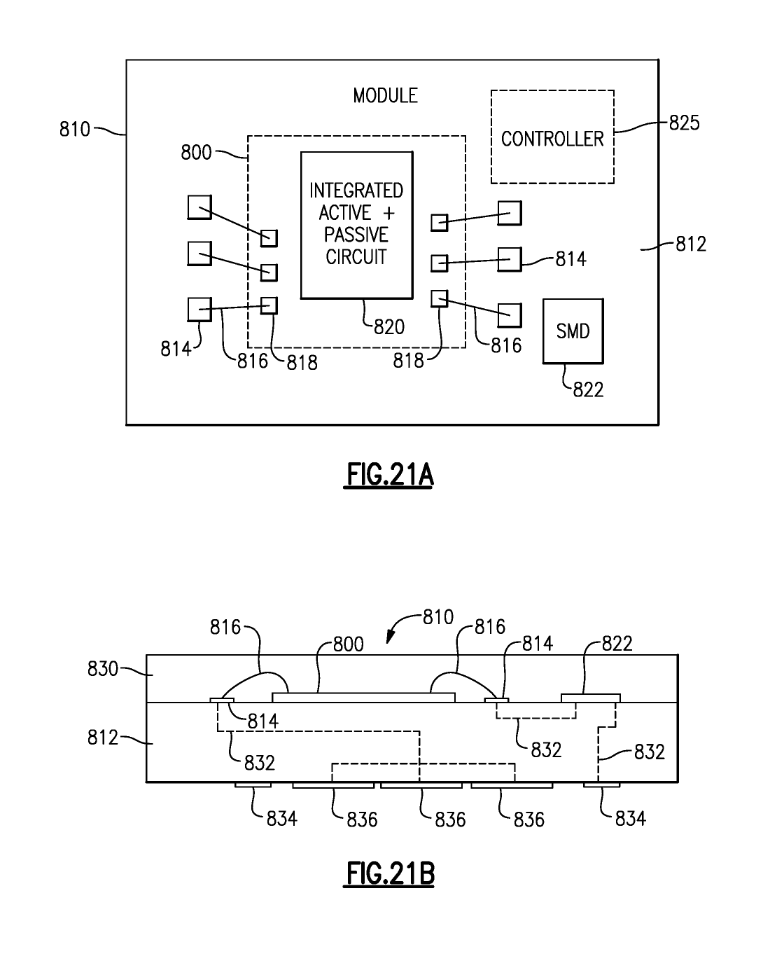

FIG. 19 shows a process 1300 that can be implemented to integrate passive devices in an SOI device or structure to form a dual-tier structure having one or more features as described herein. FIG. 20 shows examples of various stages of the fabrication processes of FIG. 19. In the examples of FIGS. 19 and 20, it will be understood that the various blocks, or stages, may or may not be performed in the example sequences illustrated. Furthermore, some of the illustrated/described steps may be omitted in certain embodiments, or additional steps may be implemented that are not explicitly described while remaining within the scope of the present disclosure. Certain of the features illustrated in FIG. 20 may be similar in certain respects to certain features illustrated in figures described above, and therefore, for simplicity, detailed description of such features may not be provided here.

At block 1302, the process 1300 involves providing at least a portion of an SOI wafer having one or more devices and/or connections formed or otherwise associated therewith, as described in various embodiments above. The corresponding structure 1401 may be a standard SOI structure including one or more of the following: a bulk substrate 1406, such as a silicon substrate; a buried oxide layer 1404 formed above the substrate; one or more transistor devices 1450, or other active devices, in an active area of the structure 1401; one or more metal connections 1410; one or more through-oxide vias 1408; and a passivation layer 1414 encompassing at least part of the active area of the structure 1401 and a passive area of the structure 1401. The metal connections 1410 may be configured as a passive metal stack, which may have relatively limited metallization.

The silicon substrate 1406 may be utilized as a handle wafer, providing structural stability for the structure 1401. At block 1304, the process 1300 involves applying a temporary handle wafer 1461 to provide stability for a layer transfer process and removing the silicon substrate 1406, to thereby create the layer-transferred active die/wafer structure 1403. In certain embodiments, the temporary handle wafer may be applied to a top side of structure 1403 prior to removal of the substrate layer 1406.

At block 1306, the process 1300 involves applying a replacement substrate 1466 to the structure and removing the temporary handle wafer 1461. The substrate 1466 may advantageously provide a low-loss substrate that is suited for integrated passive device (IPD) processing, such as high-linearity/resistivity substrate. The process 1300 may further involve applying an interface layer 1464 prior to applying the replacement substrate 1466. In certain embodiments, the interface layer may promote adhesion of the replacement substrate layer 1466.

In certain embodiments, the replacement substrate 1466 may be a high-resistivity substrate, such as glass, high-resistivity silicon, porous silicon, or other high-resistivity material. The structure 1405 may be used as a starting wafer for an IPD process. For example, the structure 1405 may be provided to a separate IPD process for forming thereon integrated passive devices. At block 1308, the process 1300 involves building additional processing on top of the wafer, which may be performed at a wafer level prior to cutting the wafer into dies. Block 1308 of the process 1300 may involve forming one or more dielectric 1421 and/or metal layers 1423 to implement the desired passive device(s). The passive device layer(s) 1423 may be implemented through one or more mask layer additions to the top-side of the structure 1405, such as approximately six or seven mask layers in some embodiments. The resulting structure 1407 is shown in FIG. 20, where the one or more additional metal layers 1423 may be at least partially covered by dielectric material and/or passivation layer(s) 1421. In certain embodiments, the passivation layers 1421 and/or metal layers 1423 may be used to form one or more passive devices. For example, one or more passive devices may be formed as part of a backend bump and/or metal (e.g., copper) pillar processing using existing redistribution layer (RDL) metal and/or dielectric layers.

The structure 1407 advantageously provides a single-die, dual-tier solution in place of traditional two-die solutions for associating active devices and passive devices. As an alternative to the two-die solution shown in FIG. 17, the structure 1407 illustrated in FIG. 20 and described herein may provide for reduced size and/or improved performance. Furthermore, the high-resistivity substrate 1466 may provide further benefits compared to the silicon substrate 1406. In view of the relative thickness of the metals 1423 associated with the integrated passive device(s), the top surface of the structure 1407 may have substantial morphology (e.g., 10-20 μm or more) where the dielectric 1421 is non-planarizing. Therefore, it may be advantageous to perform the layer transfer process described in connection with blocks 1304 and 1306 prior to forming the passive device(s) on the structure.

In certain embodiments, as shown in structure 1407, the metal layers/connections 1423 associated with the integrated passive device(s) may at least partially overlap the metal layers/connections 1410 associated with the active device(s) 1450 in a lateral direction. That is, the metal layers 1423 may be at least partially above the metal layers 1410 and/or active device(s) 1450, thereby potentially allowing for a reduced size/footprint when disposed in a chip package or the like.

The structure 1407 may be substantially similar in certain respects to the starting wafer 1206 of the IPD 1200 illustrated in FIG. 18 and described above, with the addition of a relatively thin (e.g., approximately 10 μm) layer 1480 that contains active SOI circuitry. The IPD processing of FIGS. 19 and 20 may be similar to other IPD process, and may include similar backgrinding and SAW operations, for example. The resulting structure 1407 may provide a combination dual-tier structure including SOI and IPD. Therefore, combined active and passive functionality may be achieved without the need to produce a second, separate IPD die or wafer.

Although certain embodiments are disclosed herein in the context of integrated active and passive layers through single- or double-layer transfer processes, combined active and passive wafers/dies may be formed through wafer bonding process(es) in certain embodiments. For example, an integrated passive device (IPD) wafer may be fabricated separately from an active device wafer (e.g., SOI wafer), wherein after such separate fabrication, the two wafers, or dies from separate wafers, may be combined through a wafer bonding process. With respect to wafer bonding of IPD and active wafers/dies, it may be advantageous for the respective passive and active dies to be approximately the same size, or otherwise aligned to allow for effective wafer bonding.

Furthermore, although certain processes disclosed herein involve fabrication of integrated active/passive structures using a layer transfer to a replacement low-loss substrate, such as glass, porous silicon, or the like (e.g., layer 1466 in FIG. 20), in certain embodiments, integrated passive devices may be formed above active SOI wafers/layers without transfer to a low-loss (e.g., high-linearity) substrate. For example, with respect to FIG. 20, the structure 1407 may comprise the original silicon substrate layer 1406 in place of the interface layer 1464 and/or replacement substrate 1466 shown and described above.

Examples of Implementations in Products

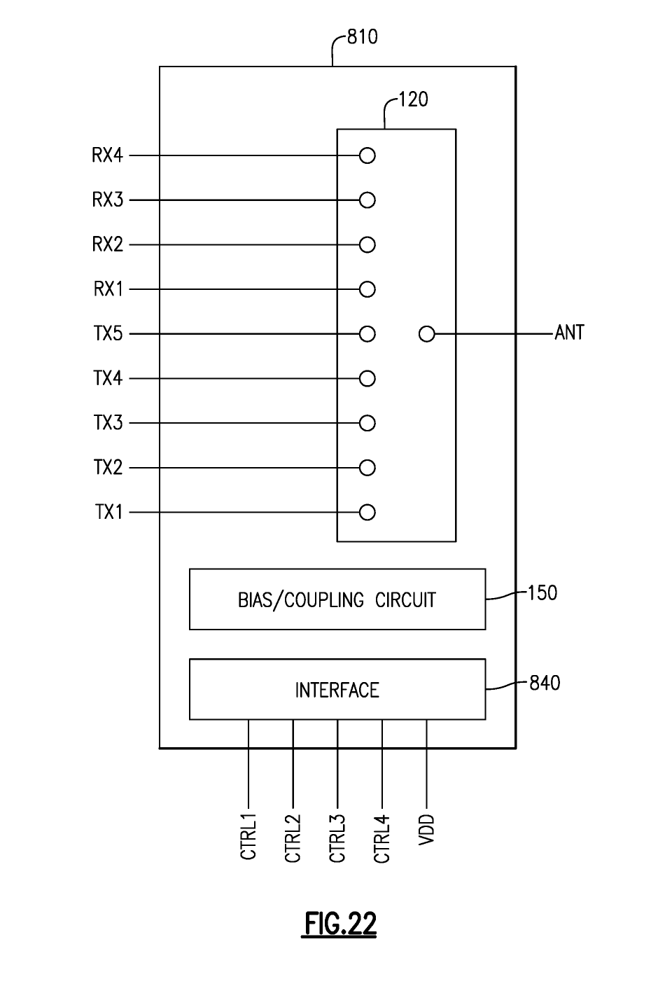

In some embodiments, one or more die having one or more features described herein can be implemented in a packaged module. An example of such a module is shown in FIGS. 21A (plan view) and 21B (side view). A module 810 is shown to include a packaging substrate 812. Such a packaging substrate can be configured to receive a plurality of components, and can include, for example, a laminate substrate. The components mounted on the packaging substrate 812 can include one or more dies. In the example shown, a die 800 having integrated active and passive devices, as described herein, is shown to be mounted on the packaging substrate 812. The die 800 can be electrically connected to other parts of the module (and with each other where more than one die is utilized) through connections such as connection-wirebonds 816. Such connection-wirebonds can be formed between contact pads 818 formed on the die 800 and contact pads 814 formed on the packaging substrate 812. In some embodiments, one or more surface mounted devices (SMDs) 822 can be mounted on the packaging substrate 812 to facilitate various functionalities of the module 810.

In some embodiments, the packaging substrate 812 can include electrical connection paths for interconnecting the various components with each other and/or with contact pads for external connections. For example, a connection path 832 is depicted as interconnecting the example SMD 822 and the die 800. In another example, a connection path 832 is depicted as interconnecting the SMD 822 with an external-connection contact pad 834. In yet another example a connection path 832 is depicted as interconnecting the die 800 with ground-connection contact pads 836.

In some embodiments, a space above the packaging substrate 812 and the various components mounted thereon can be filled with an overmold structure 830. Such an overmold structure can provide a number of desirable functionalities, including protection for the components and wirebonds from external elements, and easier handling of the packaged module 810.

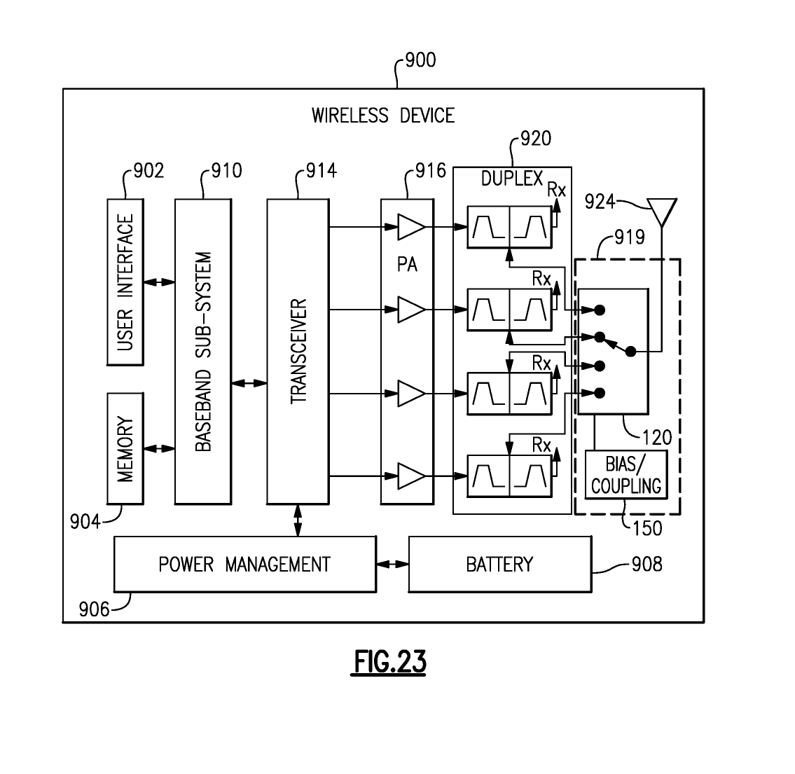

FIG. 22 shows a schematic diagram of an example switching configuration that can be implemented in the module 810 described in reference to FIGS. 21A and 21B. Although described in the context of a switch circuit and the bias/coupling circuit being on the same die (e.g., example configuration of FIG. 21A), it will be understood that packaged modules can be based on other configurations. In the example, the switch circuit 120 is depicted as being an SP9T switch, with the pole being connectable to an antenna and the throws being connectable to various Rx and Tx paths. Such a configuration can facilitate, for example, multi-mode multi-band operations in wireless devices.

The module 810 can further include an interface for receiving power (e.g., supply voltage VDD) and control signals to facilitate operation of the switch circuit 120 and/or the bias/coupling circuit 150. In some implementations, supply voltage and control signals can be applied to the switch circuit 120 via the bias/coupling circuit 150.

Wireless Device Implementation

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

FIG. 23 schematically depicts an example wireless device 900 having one or more advantageous features described herein. In the context of various switches and various biasing/coupling configurations as described herein, a switch 120 and a bias/coupling circuit 150 can be part of a module 919, which may include integrated active and passive devices in accordance with one or more of the IPD processing on SOI layer transfer substrate processes and embodiments disclosed herein. Furthermore, other components of the device 900 may include integrated active/passive die(s) as described herein, such as the power amplifier module 914, duplexer 920 and/or other components or combinations thereof. In some embodiments, the switch module 919 can facilitate, for example, multi-band multi-mode operation of the wireless device 900.

In the example wireless device 900, a power amplifier (PA) module 916 having a plurality of PAs can provide an amplified RF signal to the switch 120 (via a duplexer 920), and the switch 120 can route the amplified RF signal to an antenna. The PA module 916 can receive an unamplified RF signal from a transceiver 914 that can be configured and operated in known manners. The transceiver can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 919.

The baseband sub-system 910 is shown to be connected to a user interface 902 to facilitate various input and output of voice and/or data provided to and received from the user. The baseband sub-system 910 can also be connected to a memory 904 that is configured to store data and/or instructions to facilitate the operation of the wireless device, and/or to provide storage of information for the user.

In some embodiments, the duplexer 920 can allow transmit and receive operations to be performed simultaneously using a common antenna (e.g., 924). In FIG. 23, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method for fabricating dual-tier radio-frequency devices, the method comprising:
providing a silicon-on-insulator integrated circuit wafer having a semiconductor substrate and a plurality of integrated circuit devices formed thereon;
at least partially removing the semiconductor substrate from a backside of the integrated circuit wafer;
adding a low-loss replacement substrate to the backside of the integrated circuit wafer; and
forming an integrated passive device over each of the plurality of integrated circuit devices after the adding of the low-loss replacement substrate to form a dual-tier wafer.

2. The method of claim 1 further comprising singulating the dual-tier wafer to form a plurality of dual-tier radio-frequency devices.

3. The method of claim 1 wherein said forming the integrated passive devices over each of the plurality of integrated circuit devices involves bonding an integrated passive device wafer to the integrated circuit wafer using a wafer bonding process.

4. The method of claim 1 further comprising applying a carrier wafer on a front-side of the integrated circuit wafer prior to said at least partially removing the semiconductor substrate.

5. The method of claim 1 wherein the replacement substrate includes a high-resistivity substrate.

6. The method of claim 1 wherein the replacement substrate includes glass.

7. The method of claim 1 further comprising applying an interface layer to the backside of the integrated circuit wafer prior to said adding the low-loss replacement substrate.

8. The method of claim 1 wherein each of the passive devices includes one or more of a resistor, a capacitor, and an inductor.

9. The method of claim 1 wherein said forming an integrated passive device over each of the plurality of integrated circuit devices involves forming a plurality of dielectric layers on a front-side of the integrated circuit wafer and forming one or more electrical connections therein.

10. A dual-tier semiconductor die comprising:
a first tier including an integrated circuit device disposed on a low-loss substrate; and
a second tier disposed on the first tier, the second tier including an integrated passive device.

11. The dual-tier semiconductor die of claim 10 wherein the second tier is bonded to the first tier according to a wafer bonding process.

12. The dual-tier semiconductor die of claim 10 wherein the low-loss substrate is a high-resistivity substrate.

13. The dual-tier semiconductor die of claim 10 wherein the low-loss substrate is glass.

14. The dual-tier semiconductor die of claim 10 further comprising an interface layer formed between the low-loss substrate and the integrated circuit device.

15. The dual-tier semiconductor die of claim 10 wherein the integrated passive device includes one or more of a resistor, a capacitor, and an inductor.

16. The dual-tier semiconductor die of claim 10 wherein the second tier includes a plurality of dielectric layers and one or more electrical connections.

17. A radio-frequency module comprising:
a packaging substrate configured to receive a plurality of components; and
a dual-tier die disposed on the packaging substrate and having a first tier including an integrated circuit device disposed on a low-loss substrate, and a second tier disposed on the first tier, the second tier including an integrated passive device.

18. The radio-frequency module of claim 17 wherein the second tier is bonded to the first tier according to a wafer bonding process.

19. The radio-frequency module of claim 17 wherein the low-loss substrate is a high-resistivity substrate.

20. The radio-frequency module of claim 17 wherein the low-loss substrate is glass.
